(19) United States
(12) Patent Application Publication
(10) Pub. No.: US 2020/0404789 A1
(43) Pub. Date: Dec. 24, 2020

(54) WIRING BOARD INCLUDING METAL PIECE AND METHOD FOR MANUFACTURING WIRING BOARD INCLUDING METAL PIECE

(71) Applicant: Fujikura Ltd., Tokyo (JP)

(72) Inventor: Takaharu Hondo, Chiba (JP)

(73) Assignee: Fujikura Ltd., Tokyo (JP)

(21) Appl. No.: 16/975,937

(22) PCT Filed: Feb. 12, 2019
(86) PCT No.: PCT/JP2019/004813

§ 371 Date: Aug. 26, 2020

(30) Foreign Application Priority Data
Feb. 28, 2018 (JP) 2018-034916

(51) Int. Cl. H05K 1/11; H05K 1/03; H05K 3/36

(52) U.S. Cl. CPC H05K 1/118; H05K 3/365; H05K 1/0393

(57) ABSTRACT

A wiring board includes: a flexible printed circuit board that includes: a base having a first opening; a wiring pattern formed on the base; and a cover lay that includes an adhesive layer adhering to the wiring pattern and that has a second opening; and a metal cover that covers at least a part of the first opening from below. The wiring pattern contacts the metal cover through the first opening, and is bonded to the metal cover. At least a part of the second opening overlaps the first opening in a plan view. A part of the cover lay overlaps the first opening in a plan view.

### CROSS-REFERENCE TO RELATED APPLICATIONS

The present application claims priority based on Japanese Patent Application No. 2018-034916 filed on Feb. 28, 2018, the content of which is incorporated herein by reference.

### TECHNICAL FIELD

The present invention relates to a wiring board including a metal piece and a method for manufacturing a wiring board including a metal piece.

### BACKGROUND

In the related art, as shown in Patent Document 1 below, a wiring board including a metal piece, which includes a wiring board and a metal piece bonded to the wiring board, is known. In this wiring board including a metal piece, the wiring is in a bent state in order to partially bond the wiring and the metal piece in the wiring board.

### CITATION LIST

### [Patent Document 1]

Japanese Unexamined Patent Application, First Publication No. 2000-307202

However, in the configuration of the above-described Patent Document 1, since the wiring is in a bent state, there is a possibility that stress concentrates on the bent portion and the wiring is broken.

Further, in the configuration of the above-described Patent Document 1, it is necessary to bend at least one of the wiring and the metal piece in advance before bonding, and the manufacturing efficiency needs to be improved.

### SUMMARY

One or more embodiments of the present invention provide a wiring board including a metal piece, which can prevent the wiring from breaking and improve the manufacturing efficiency.

A metal piece (i.e., metal cover) according to one or more embodiments includes: a flexible printed circuit board that has a base material (i.e., base) having a first opening, a wiring pattern formed on the base material, and a cover lay having a second opening and being adhered to the wiring pattern by an adhesive layer; and a metal piece covering at least a part of the first opening from below, in which the wiring pattern is in contact with the metal piece through the first opening, and is bonded to the metal piece, and at least a part of the second opening overlaps the first opening in a plan view, and a part of the cover lay overlaps the first opening in a plan view.

According to one or more embodiments, in a plan view, at least a part of the second opening overlaps the first opening, and the metal piece covers at least part of the first opening from below. Therefore, when the bonding tool is pressed against the wiring pattern through the second opening and the wiring pattern is deformed so as to pass through the first opening, the wiring pattern and the metal piece can be brought into contact with each other. Then, since the wiring pattern and the metal piece can be bonded in this state, manufacturing efficiency can be improved.

The cover lay is adhered to the wiring pattern by an adhesive layer, and a part of the cover lay overlaps the first opening in plan view. Therefore, when the wiring pattern is deformed as described above, the portion of the cover lay overlapping the first opening can be bent downward. Thus, it is possible to prevent a large local stress from being applied to the wiring pattern. Therefore, the occurrence of disconnection of the wiring pattern can be suppressed.

A wiring board including a metal piece according to one or more embodiments includes: a flexible printed circuit board that has a lower cover lay having a first opening, an upper cover lay having a second opening, and a wiring pattern disposed between the lower cover lay and the upper cover lay; and a metal piece covering at least a part of the first opening from below, in which the wiring pattern is in contact with the metal piece through the first opening, and is bonded to the metal piece, the lower cover lay has a lower adhesive layer in contact with the wiring pattern, and a lower film adhered to the wiring pattern by the lower adhesive layer, and at least a part of the first opening is located inside the second opening in a plan view.

According to one or more embodiments, when the wiring pattern is deformed toward the inside of the first opening, the lower adhesive layer interposed between the edge of the lower film and the wiring pattern can prevent the wiring pattern from being broken or disconnected. Therefore, the occurrence of disconnection of the wiring pattern can be suppressed.

Further, the elastic modulus of the lower adhesive layer may be smaller than the elastic modulus of the lower film.

In this case, since the lower adhesive layer has a smaller elastic modulus and is more easily deformed, the occurrence of disconnection of the wiring pattern can be suppressed more reliably.

Further, the upper cover lay may include an upper adhesive layer that is in contact with the wiring pattern, and an upper film that is adhered to the wiring pattern by the upper adhesive layer.

According to this structure, the adhesive layer located between the film and the wiring pattern functions as a cushioning material. Therefore, even when the films of the upper and lower cover lays expand and contract more greatly than the wiring pattern due to temperature changes or the like, the stress acting on the wiring pattern can be reduced.

Further, the flexible printed circuit board may have a symmetrical laminating order with respect to the wiring pattern in an up-down direction (i.e., height direction).

In this case, the amount of deformation of each member due to temperature change or the like is substantially equal on the upper side and the lower side of the wiring pattern. Therefore, the stress acting on the wiring pattern can be further reduced.

A method for manufacturing a wiring board including a metal piece according to one or more embodiments includes: a preparation step of preparing a flexible printed circuit board that has a base material having a first opening, a cover lay having a second opening, and a wiring pattern sandwiched between the base material and the cover lay; a deformation step of pressing the wiring pattern through the second opening by a bonding tool, and deforming the wiring pattern toward a metal piece; and a bonding step of bonding together the wiring pattern and the metal piece using the bonding tool.

According to one or more embodiments, the deformation step and the bonding step can be performed substantially at the same time. Therefore, for example, the manufacturing efficiency can be improved as compared with the case where the wiring pattern or the metal piece is deformed in advance before the bonding step.

According to the above-mentioned embodiments, it is possible to provide a wiring board including a metal piece, which can prevent the wiring from breaking and improve the manufacturing efficiency.

### BRIEF DESCRIPTION OF DRAWINGS

FIG. 1 is a cross-sectional view of a wiring board including a metal piece according to a first embodiment.

FIG. 2 is a plan view of the wiring board including a metal piece in FIG. 1 as viewed from above.

FIGS. 3A-3F are diagrams illustrating a manufacturing step of the wiring board including a metal piece in FIG. 1.

FIG. 4 is an explanatory diagram when ultrasonic bonding is used in the bonding step.

FIG. 5 is a cross-sectional view of a wiring board including a metal piece according to a second embodiment.

FIG. 6 is a plan view of the wiring board including a metal piece in FIG. 5 as viewed from above.

FIGS. 7A-7F are diagrams illustrating a manufacturing step of the wiring board including a metal piece in FIG. 5.

FIG. 8 is an enlarged view of the bonding portion in FIG. 5.

### DETAILED DESCRIPTION

### First Embodiment

Hereinafter, a wiring board including a metal piece of the present embodiment will be described with reference to the drawings. The present invention is not limited to the embodiments below.

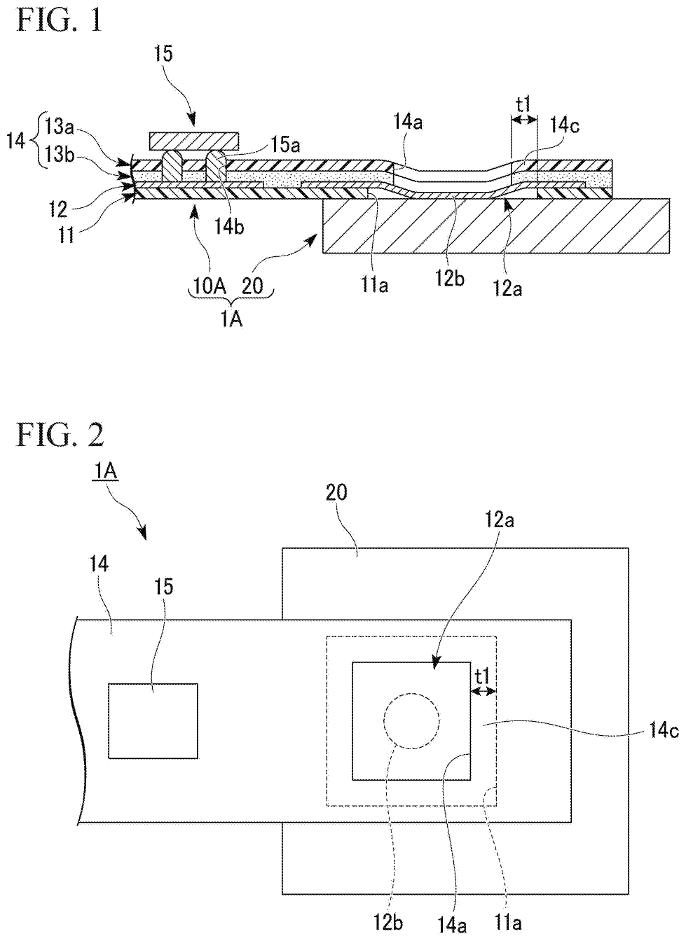

As shown in FIG. 1, the wiring board 1A with metal piece includes a flexible printed circuit (FPC) board 10A and a metal piece (metal cover) 20 bonded to a wiring pattern 12 of the flexible printed circuit board 10A.

The flexible printed circuit board 10A includes a base material (base) 11, a wiring pattern 12, a cover lay (upper cover lay) 14, and an electronic component 15. The cover lay 14 has a film (upper film) 13a and an adhesive layer (upper adhesive layer) 13b applied to the film 13a. The flexible printed circuit board 10A is highly flexible and is configured such that the wiring pattern 12 functions even when the flexible printed circuit board 10A is largely bent.

### (Direction Definition)

In the present embodiment, the thickness direction of the flexible printed circuit board 10A is simply referred to as the thickness direction. In addition, along the thickness direction, the cover lay 14 side is referred to as an upper side, and the base material 11 side is referred to as a lower side. Further, viewing from the thickness direction is referred to as plan view.

The flexible printed circuit board 10A has a laminated structure in which the base material 11, the wiring pattern 12, and the cover lay 14 are laminated in this order from below to above.

An electronic component 15 is mounted on the flexible printed circuit board 10A. As the electronic component 15, capacitors, resistors, thermistors, ICs, LEDs and the like are used. Further, another circuit board may be mounted as the electronic component 15 on the flexible printed circuit board 10A.

The terminal 15a of the electronic component 15 is electrically connected to the wiring pattern 12 through the mounting opening 14b formed in the cover lay 14. The number of electronic components 15 may be one or more. Further, a plurality of types of electronic components 15 may be mounted on the flexible printed circuit board 10A.

### (Base Material)

The base material 11 is formed in a thin film shape and is located in the lowermost layer of the flexible printed circuit board 10A. As the base material 11, a flexible and insulating material such as polyimide or liquid crystal polymer can be used. In the present embodiment, a polyimide film having a thickness of 25 μm is used as the base material 11. A first opening 11a is formed in the base material 11. As shown in FIG. 2, the first opening 11a is formed in a square shape in plan view. In the present embodiment, the length of one side of the square-shaped first opening 11a is 7 mm. The shape and dimension of the first opening 11a are not limited to the above, and may be rectangular, circular, elliptical, or the like.

### (Wiring Pattern)

The wiring pattern 12 is formed on the base material 11. As the material of the wiring pattern 12, for example, a thin film of a conductive metal such as copper, stainless steel, or aluminum can be used. In the present embodiment, as the wiring pattern 12, an electrolytic copper foil having a thickness of 35 μm is used. The wiring pattern 12 can be formed on the base material 11 by, for example, a subtractive method or a semi-additive method. An adhesive layer may be provided between the wiring pattern 12 and the base material 11 to adhere them to each other.

The wiring pattern 12 is sandwiched between the base material 11 and the cover lay 14. A first opening 11a is formed in the base material 11, and a second opening 14a described later is formed in the cover lay 14. At least parts of the first opening 11a and the second opening 14a overlap each other in a plan view. Therefore, at least a part of the wiring pattern 12 is exposed through the first opening 11a and the second opening 14a. In the present embodiment, the portion of the wiring pattern 12 exposed through the first opening 11a and the second opening 14a is referred to as an exposed portion 12a.

The part of the exposed portion 12a is bent downward (toward the metal piece 20), and is bonded to the metal piece 20. A part of the exposed portion 12a, bonded to the metal piece 20, is referred to as a bonding portion 12b. In the present embodiment, the exposed portion 12a is formed in a square shape and the bonding portion 12b is formed in a circular shape in the plan view shown in FIG. 2.

### (Adhesive Layer)

The adhesive layer 13b bonds the film 13a of the cover lay 14 and the wiring pattern 12 to each other. As a material for the adhesive layer 13b, resin having an insulating property and an adhesive property such as an epoxy type, an acrylic type, or a polyimide type can be used. In the present embodiment, an epoxy adhesive having a thickness of 25 μm is used as the adhesive layer 13b. The adhesive layer 13b is provided on the lower surface of the portion of the film 13a excluding the second opening 14a.

### (Cover Lay)

The cover lay 14 covers the wiring pattern 12 and is located in the uppermost layer of the flexible printed circuit board 10A. As the film 13a of the cover lay 14, a flexible and insulating material such as polyimide or liquid crystal polymer can be used. The material of the film 13a may be the same as or different from the material of the base material 11. In the present embodiment, a polyimide film having a thickness of 25 μm similar to that of the base material 11 is used as the film 13a. The adhesive layer 13b is applied to the lower surface of the film 13a.

A second opening 14a is formed in the cover lay 14. The second opening 14a can be formed by applying laser beam machining, die machining, numerical control machining (NC machining), or the like to the cover lay 14. The wiring pattern 12 is exposed upward through the second opening 14a.

As shown in FIG. 2, the second opening 14a is smaller than the first opening 11a and is formed at a position overlapping the first opening 11a in plan view. The second opening 14a is formed in a square shape in plan view. In the present embodiment, the length of one side of the second opening 14a, which is a square, is 6 mm, and the positions of the centroids of the second opening 14a and the first opening 11a (a square having the length of one side of 7 mm) substantially match each other in plan view. Therefore, the cover lay 14 overlaps the first opening 11a with a width of 0.5 mm along the opening edge of the second opening 14a. A portion of the cover lay 14 that overlaps the first opening 11a is referred to as an overlapping portion 14c. Further, the width of the overlapping portion 14c in plan view is referred to as the overlap amount t1. In other words, the overlap amount t1 is the distance between the opening edges of the first opening 11a and the second opening 14a in the overlapping portion 14c.

In the present embodiment, the overlapping portion 14c is formed in a square frame shape having a width of 0.5 mm in a plan view. The width of the overlapping portion 14c (overlap amount t1) is substantially uniform along the opening edge of the first opening 11a.

The shape and dimension of the second opening 14a are not particularly limited, and may be rectangular, circular, elliptical, or the like. Further, in plan view, the position of the centroid of the second opening 14a may not match the position of the centroid of the first opening 11a. That is, the shape of the overlapping portion 14c is not particularly limited, and the overlap amount t1 may be nonuniform along the opening edge of the second opening 14a. However, at least a part of the cover lay 14 may cover the first opening 11a, and the overlapping portion 14c may be formed. Further, the overlap amount t1 may be partially 0 mm or may be 0.1 mm or more at least in part. As will be described later in detail, the larger the overlap amount t1, the easier the overlapping portion 14c is bent downward, and the stress and tension acting on the wiring pattern 12 can be reduced.

### (Metal Piece)

The metal piece 20 is formed of a metal such as aluminum into a film shape, a rod shape, or a plate shape. The material and shape of the metal piece 20 may be changed as appropriate. In the present embodiment, plate-shaped aluminum (A1050) with a thickness of 1 mm is used as the metal piece 20.

The metal piece 20 covers the first opening 11a of the base material 11 from below. In the illustrated example, the metal piece 20 covers the entire first opening 11a, but may cover at least a part thereof. The metal piece 20 is bonded to the bonding portion 12b of the wiring pattern 12 and is electrically connected to the wiring pattern 12.

### (Manufacturing Method)

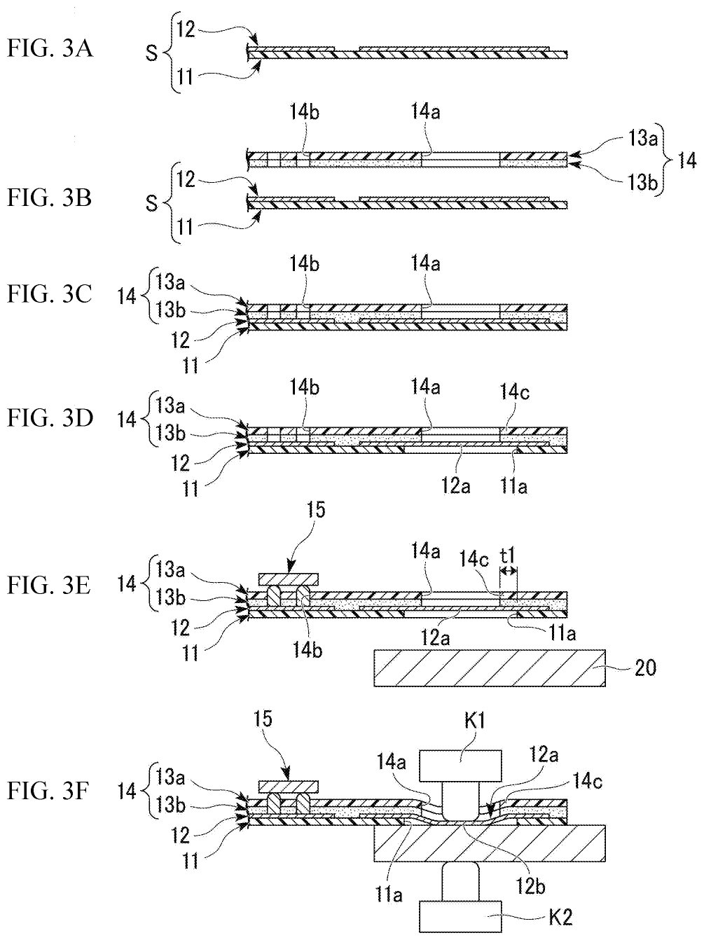

Next, an example of a method for manufacturing the wiring board 1A including a metal piece, having the above-described configuration, will be described with reference to FIGS. 3A-3F.

### (Preparation Step)

First, a preparation step of preparing the flexible printed circuit board 10A is performed. In the preparation step, as shown in FIG. 3A, a sheet S having a wiring pattern 12 formed on a base material 11 is prepared.

Next, as shown in FIG. 3B, the cover lay 14 having the second opening 14a and the mounting opening 14b formed therein is made to face the wiring pattern 12 of the sheet S. At this time, a semi-cured adhesive that becomes the adhesive layer 13b has been applied to the lower surface of the film 13a of the cover lay 14.

Next, the cover lay 14 and the sheet S are aligned. As an alignment method, a positioning pin or a position control device by image processing can be used.

Next, as shown in FIG. 3C, the cover lay 14 is laminated on the sheet S, and the cover lay 14 and the sheet S are integrated by heating press. The heating press may be in a range of a temperature of 100 to 200° C., a pressure of 0.1 to 10 MPa, and a pressing time of 1 to 120 minutes. Further, heating may be performed in an oven after the heating press as needed.

Next, as shown in FIG. 3D, the base material 11 is partially removed to form the first opening 11a. As a removing method, laser machining, etching machining, or the like can be used. By forming the first opening 11a in the base material 11, the wiring pattern 12 is partially exposed. At this time, the first opening 11a is formed larger than the second opening 14a such that the cover lay 14 overlaps by a dimension t. By forming the first opening 11a, the exposed portion 12a of the wiring pattern 12 is exposed downward.

Next, as shown in FIG. 3E, the electronic component 15 is mounted on the flexible printed circuit board 10A. As a mounting method, solder, silver paste, ultrasonic bonding, wire bonding, or the like can be used.

Next, the metal piece 20 is positioned below the flexible printed circuit board 10A, and is disposed such that the metal piece 20 faces the exposed portion 12a in the thickness direction.

### (Deformation Step)

Next, as shown in FIG. 3F, a deformation step of deforming the exposed portion 12a of the wiring pattern 12 toward the metal piece 20 is performed. In the deformation step, the metal piece 20 and the flexible printed circuit board 10A are positioned, and the bonding tool K1 used in the bonding step described below is pressed against the exposed portion 12a through the second opening 14a. Thus, the exposed portion 12a is deformed so as to extend downward through the first opening 11a and comes into contact with the metal piece 20. At this time, the overlapping portion 14c of the cover lay 14 also bends downward.

### (Bonding Step)

Next, a bonding step of bonding together the wiring pattern 12 and the metal piece 20 is performed. In the present embodiment, a case where a direct current type resistance welder is adopted will be described. In the case of resistance welding, welding electrodes are used as the bonding tools K1, K2. The bonding tool K1 is in contact with the exposed portion 12a from above and is electrically connected to the metal piece 20 through the exposed portion 12a. The bonding tool K2 is in contact with the metal piece 20 from below at a position overlapping the bonding tool K1 in a plan view. That is, a pair of bonding tools K1, K2 are in a state of sandwiching the exposed portion 12a and the metal piece 20 in the thickness direction.

Next, in a state where the bonding tools K1, K2 are pressed against the metal piece 20, a voltage is applied to the bonding tools K1, K2 and a current flows. The direction of the current is any, and may be a direction from the bonding tool K1 to the bonding tool K2 or vice versa. Further, the direction of the current may be alternately changed between the bonding tools K1, K2 at predetermined time intervals. The welding conditions in the present embodiment are a current of 2 kA, a welding time of 10 milliseconds, and a pressing force of 16 kgf. When a current flows between the pair of bonding tools K1, K2, heat is generated due to contact resistance at the interface between the wiring pattern 12 and the metal piece 20. Due to this heat, the wiring pattern 12 or the metal piece 20 is melted, and these can be welded (bonded). When the tip of the bonding tool K1 is circular, the bonding portion 12b is formed in a circular shape in a plan view. When resistance welding is used in the bonding step, a fusion portion (nugget) and an alloy layer can be formed at the interface with the metal piece 20 in the bonding portion 12b. The nugget is a part that is solidified again after being melted by heat.

In addition, in the bonding step, a parallel current type resistance welder may be used. In this case, although not shown, the bonding tool K2 is in contact with the bonding tool K1 from above or below the metal piece 20 with a predetermined space therebetween in a plan view.

Incidentally, in the above deformation step, when the cover lay 14 does not have the overlapping portion 14c, the wiring pattern 12 is strongly pressed against the opening edge of the first opening 11a, and a large local stress can occur on the wiring pattern 12. The wiring pattern 12 may be broken due to this stress.

On the other hand, in the present embodiment, the cover lay 14 partially covers the first opening 11a. Therefore, when the exposed portion 12a is pressed downward, the overlapping portion 14c of the cover lay 14 is also bent downward. Thus, it is possible to prevent a large local stress from acting on the wiring pattern 12. Further, it is possible to prevent the wiring pattern 12 from being broken due to local stress.

Note that the larger the overlap amount t1, the more gently (with a large radius of curvature) the downward bending of the overlapping portion 14c. Therefore, breakage of the wiring pattern 12 can be suppressed more reliably. The overlap amount t1 may depend on the material and thickness of the film 13a of the cover lay 14, but may be 0.5 mm or more, for example.

As described above, according to the present embodiment, in plan view, at least a part of the second opening 14a overlaps the first opening 11a, and the metal piece 20 covers at least a part of the first opening 11a from below. Therefore, the bonding tool K1 is pressed against the exposed portion 12a of the wiring pattern 12 through the second opening 14a, the exposed portion 12a is deformed so as to pass through the first opening 11a, and the exposed portion 12a and the metal piece 20 can be brought into contact with each other. Then, the exposed portion 12a and the metal piece 20 can be bonded in this state. In this way, the deformation step and the bonding step can be performed substantially at the same time, so that the manufacturing efficiency can be improved.

The cover lay 14 is adhered to the wiring pattern 12 by the adhesive layer 13b, and a part of the cover lay 14 overlaps the first opening 11a in plan view. Therefore, when the exposed portion 12a is deformed as described above, the overlapping portion 14c of the cover lay 14 can be bent downward. Thus, it is possible to prevent a large local stress from acting on the wiring pattern 12. Therefore, the occurrence of disconnection of the wiring pattern 12 can be suppressed.

It should be noted that the technical scope of the present invention is not limited to the above-described embodiment, and various modifications can be made without departing from the spirit of the present invention.

For example, in the above-described embodiment, the first opening 11a and the second opening 14a are disposed in a state in which they are substantially similar to each other and their centroids match each other. However, the positions of the centroids of the first opening 11a and the second opening 14a may deviate in a plan view. Further, the shapes of the first opening 11a and the second opening 14a may not be substantially similar to each other.

Further, in the above-described embodiment, the case where the wiring pattern 12 and the metal piece 20 are bonded by using resistance welding has been described, but the bonding method may be appropriately changed. For example, ultrasonic bonding or laser bonding may be adopted in the bonding step.

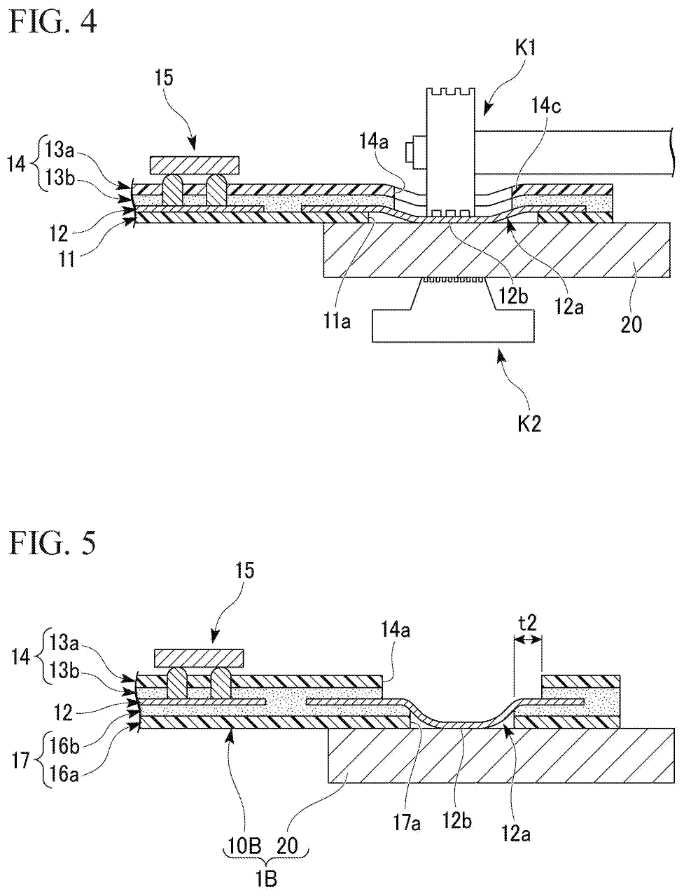

When ultrasonic bonding is used in the bonding step, a horn and an anvil are used as the bonding tools K1, K2, as shown in FIG. 4. Then, the wiring pattern 12 and the metal piece 20 are sandwiched and pressed by the horn and the anvil. Thus, similarly to the above-described embodiment, the wiring pattern 12 is deformed during pressurization and comes into contact with the metal piece 20 (deformation step). When the horn vibrates in this state in the axial direction, the vibration is transmitted to the wiring pattern 12 and the metal piece 20, and frictional heat is generated at the contact surface therebetween. Due to the frictional heat or the like, the wiring pattern 12 and the metal piece 20 are diffusion-bonded (thermocompression-bonded) or metallurgically bonded. Thus, the wiring pattern 12 and the metal piece 20 can be bonded (bonding step). In the deformation step and the bonding step, the relationship in the up-down direction between the flexible printed circuit board 10A and the metal piece 20 may be reversed. When ultrasonic bonding is used, the wiring pattern 12 and the metal piece 20 can be bonded at a relatively low temperature.

### Second Embodiment

Next, a second embodiment of the present invention will be described, but the basic configuration is the same as that of the first embodiment. Therefore, the same reference numerals are given to similar components, the explanation thereof will be omitted, and only difference will be described.

In the present embodiment, the base material 11 in the first embodiment is replaced with the lower cover lay 17.

As shown in FIG. 5, the wiring board 1B including a metal piece of the present embodiment includes a flexible printed circuit board 10B, and a metal piece 20 bonded to the wiring pattern 12 of the flexible printed circuit board 10B.

The flexible printed circuit board 10B includes a wiring pattern 12, an upper cover lay 14, a lower cover lay 17, and an electronic component 15. The upper cover lay 14 has a film (upper film) 13a and an adhesive layer (upper adhesive layer) 13b applied to the film 13a. The lower cover lay 17 has a film (lower film) 16a and an adhesive layer (lower adhesive layer) 16b applied to the film 16a. The flexible printed circuit board 10B is highly flexible and is configured such that the wiring pattern 12 functions even when the flexible printed circuit board 10B is largely bent.

As the lower film 16a, the same material as the upper film 13a described in the first embodiment can be used. Note that different materials may be used for the lower film 16a and the upper film 13a.

The same material as the upper adhesive layer 13b described in the first embodiment can be used for the lower adhesive layer 16b. Note that different materials may be used for the lower adhesive layer 16b and the upper adhesive layer 13b.

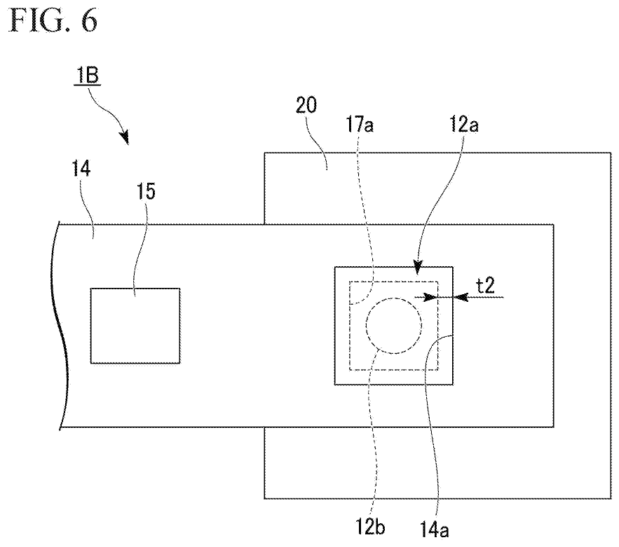

The lower cover lay 17 has a first opening 17a formed therein, and the upper cover lay 14 has a second opening 14a formed therein. As shown in FIG. 6, the first opening 17a is formed in a square shape smaller than the second opening 14a in a plan view. In the present embodiment, the first opening 17a has a square shape that the length of one side is 6 mm, the second opening 14a has a square shape that the length of one side is 7 mm, and the positions of the centroids of the first opening 17a and the second opening 14a match each other in plan view. Therefore, the first opening 17a protrudes inward from the second opening 14a in a cross-sectional view (FIG. 5), and the protrusion amount t2 is 0.5 mm. Further, the protrusion amount t2 is substantially uniform along the opening edge of the first opening 17a. The protrusion amount t2 is a distance between the opening edges of the first opening 17a and the second opening 14a. The first opening 17a is located inside the second opening 14a in a plan view (FIG. 6).

Note that, similarly to the first embodiment, the positions, shapes, sizes, or the like of the first opening 17a and the second opening 14a may be appropriately changed. However, the protrusion amount t2 may be 0.1 mm or more.

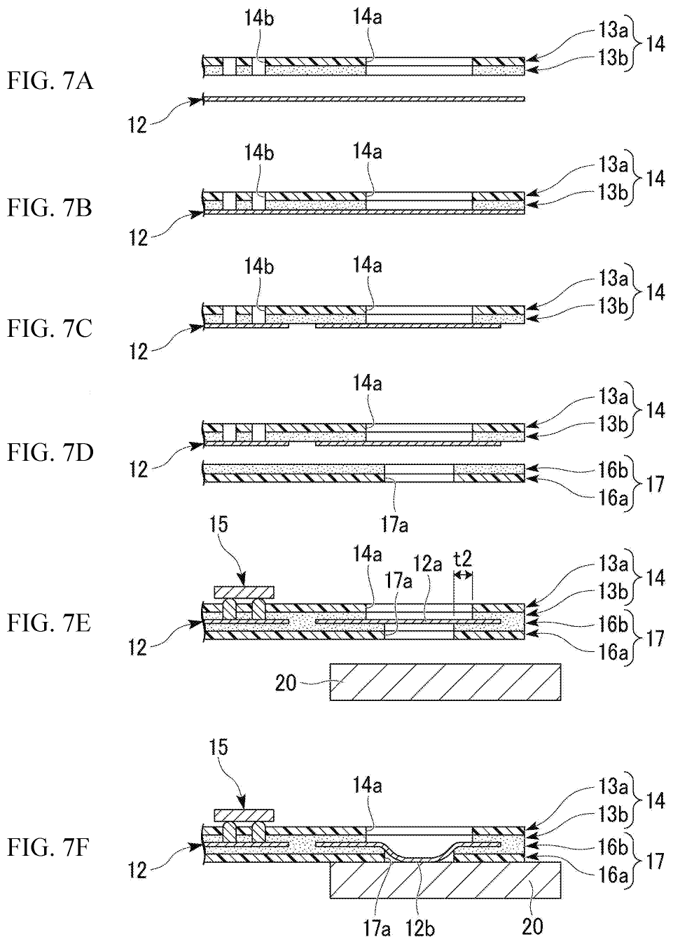

(Manufacturing Method) Next, an example of a method for manufacturing the wiring board 1B including a metal piece, having the above-described configuration, will be described with reference to FIG. 7A-7F. A description of the contents the same as in the first embodiment will be omitted.

### (Preparation Step)

First, a preparation step of preparing the flexible printed circuit board 10B is performed. In the preparation step, as shown in FIG. 7A, the metal foil to be the wiring pattern 12 is made to face the upper cover lay 14. At this time, the upper cover lay 14 has been formed with the second opening 14a in advance.

In the present embodiment, a polyimide film having a thickness of 25 μm (linear expansion coefficient: 27 ppm/K, Young's modulus: 3.5 GPa) is used as each of the films 13a, 16a, and an epoxy adhesive having a thickness of 25 μm (linear expansion coefficient: 60 ppm/K, Young's modulus: 0.4 GPa) is used as each of the adhesive layers 13b, 16b. The Young's modulus of the adhesive layers 13b, 16b may be lower than the Young's modulus of the films 13a, 16a. Specifically, the Young's modulus of the adhesive layers 13b, 16b may be 3 GPa or less, or may be 1 GPa or less, or may be 0.5 GPa or less.

Next, as shown in FIG. 7B, the upper cover lay 14 and the metal foil are aligned and integrated. Next, as shown in FIG. 7C, the metal foil is machined to obtain the wiring pattern 12.

Next, as shown in FIG. 7D, the lower cover lay 17 having the first opening 17a formed therein is made to face the lower surface of the wiring pattern 12. The size of the first opening 17a is smaller than the size of the second opening 14a, so that the protrusion amount t2 has a desired length.

Next, as shown in FIG. 7E, the adhesive layers 13b, 16b of the upper cover lay 14 and the lower cover lay 17 are bonded with the wiring pattern 12 interposed therebetween, and the electronic component 15 is mounted on the upper cover lay 14. Thus, the flexible printed circuit board 10B is obtained.

Then, by performing the same deformation step and bonding step as in the first embodiment, the wiring board 1B including a metal piece as shown in FIG. 7F is obtained.

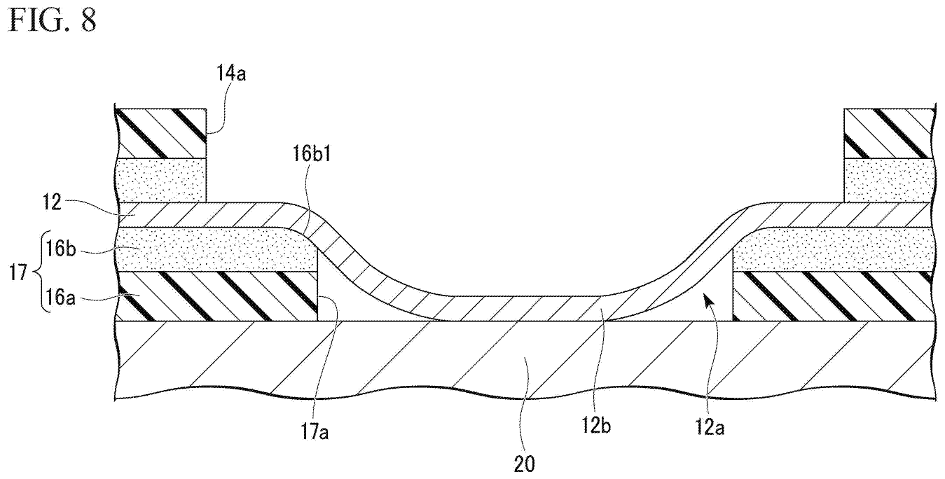

Here, when the wiring pattern 12 is deformed in the deformation step, the wiring pattern 12 is pressed against the edge of the first opening 17a. At this time, as shown in FIG. 8, the lower adhesive layer 16b is pressed downward by the wiring pattern 12 and deformed, and a curved surface 16b1 that is convex upward is formed at the opening edge of the lower adhesive layer 16b. Therefore, the wiring pattern 12 is deformed toward the metal piece 20 along the curved surface 16b1, and it is possible to prevent a large stress from being applied to the deformation start position.

Next, the effect of the wiring board 1B including the metal piece will be described.

When a temperature change is applied to the wiring board 1B including a metal piece, such as a thermal cycle test, stress due to the difference in linear expansion coefficient acts on the contact surface between the respective members. At this time, since the films 13a, 16a have a relatively high elastic modulus and are not likely to be deformed, it is difficult to change the stress on the contact surface into their own deformation, and peeling easily occurs at the interface with other members. Therefore, in the present embodiment, the adhesive layers 13b, 16b which have a small elastic modulus and are easily deformed are disposed between the wiring pattern 12 and the films 13a, 16a. With this configuration, the adhesive layers 13b, 16b function as cushioning materials, thereby preventing large stress from acting on the wiring pattern 12. Therefore, even when the temperature change is repeated, peeling of the surface of the wiring pattern 12 and large thermal stress applied to the wiring pattern 12 can be suppressed.

Further, in the present embodiment, the lower cover lay 17 has a lower adhesive layer 16b that is in contact with the wiring pattern 12, and a lower film 16a that is adhered to the wiring pattern 12 by the lower adhesive layer 16b. In plan view, at least a part of the first opening 17a is located inside the second opening 14a. With this configuration, when the wiring pattern 12 is deformed toward the inside of the first opening 17a, the lower adhesive layer 16b interposed between the edge of the lower film 16a and the wiring pattern 12 can prevent the wiring pattern 12 from being broken or disconnected. Therefore, the occurrence of disconnection of the wiring pattern 12 can be suppressed.

Further, the elastic modulus of the lower adhesive layer 16b is smaller than that of the lower film 16a, and the lower adhesive layer 16b is easily deformed, so that the occurrence of disconnection of the wiring pattern 12 can be suppressed more reliably. Further, since the curved surface 16b1 is formed at the opening edge of the lower adhesive layer 16b, it is possible to prevent a large stress from being applied to the deformation start position of the wiring pattern 12.

Further, the upper cover lay 14 has an upper adhesive layer 13b which is in contact with the wiring pattern 12 and an upper film 13a which is adhered to the wiring pattern 12 by the upper adhesive layer 13b. In this way, the wiring pattern 12 is sandwiched between the two adhesive layers 13b, 16b having a relatively low elastic modulus. Therefore, even when the upper film 13a or the lower film 16a expands or contracts more greatly than the wiring pattern 12 due to a temperature change or the like, the adhesive layers 13b, 16b located between the films 13a, 16a and the wiring pattern 12 function as a cushioning material, thereby reducing the thermal stress acting on the wiring pattern 12.

The flexible printed circuit board 10B has a symmetrical laminating order with respect to the wiring pattern 12 in the up-down direction (an up-down mirror symmetrical laminating order with respect to the wiring pattern 12.) Therefore, the amount of deformation of each member due to temperature change and the like is substantially equal on the upper side and the lower side of the wiring pattern 12. Therefore, the thermal stress acting on the wiring pattern 12 can be further reduced. The adhesive layers 13b, 16b and the films 13a, 16a may be made of the same material. In this case, the amount of deformation can be more reliably matched between the upper side and the lower side of the wiring pattern 12.

In addition, without departing from the spirit of the present invention, it is possible to appropriately replace the constituent elements in the above-described embodiments with well-known constituent elements, and the above-described embodiments and modification examples may be appropriately combined.

For example, the flexible printed circuit board 10A of the first embodiment may have a symmetrical laminating order about the wiring pattern 12 in the up-down direction. In this case, an adhesive layer may be provided between the base material 11 and the wiring pattern 12.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1A, 1B Wiring board including metal piece
10A, 10B Flexible printed circuit board
11 Base material
11a First opening
12 Wiring pattern
13a Film (upper film)
13b Adhesive layer (upper adhesive layer)
14 Cover lay (upper cover lay)
14a Second opening
16a Film (lower film)
16b Adhesive layer (lower adhesive layer)
17 Cover lay (lower cover lay)
17a First opening
K1 to K2 Bonding tool

1. A wiring board comprising:
a flexible printed circuit board that comprises:
a base having a first opening;
a wiring pattern formed on the base; and
a cover lay that comprises an adhesive layer adhering to the wiring pattern and that has a second opening; and
a metal cover that covers at least a part of the first opening from below, wherein
the wiring pattern contacts the metal cover through the first opening, and is bonded to the metal cover,
at least a part of the second opening overlaps the first opening in a plan view of the wiring board, and
a part of the cover lay overlaps the first opening in the plan view.

2. A wiring board comprising:
a flexible printed circuit board that comprises:
a lower cover lay having a first opening;
an upper cover lay having a second opening; and
a wiring pattern disposed between the lower cover lay and the upper cover lay; and
a metal cover that covers at least a part of the first opening from below, wherein
the wiring pattern contacts the metal cover through the first opening, and is bonded to the metal cover,
the lower cover lay comprises:
a lower adhesive layer contacting the wiring pattern; and
a lower film adhered to the wiring pattern via the lower adhesive layer, and a part of the first opening is located inside the second opening in a plan view of the wiring board.

3. The wiring board according to claim 2, wherein an elastic modulus of the lower adhesive layer is smaller than an elastic modulus of the lower film.

4. The wiring board according to claim 2, wherein
the upper cover lay comprises:
an upper adhesive layer that contacts the wiring pattern; and
an upper film adhered to the wiring pattern via the upper adhesive layer.

5. The wiring board according to claim 1, wherein a laminating order of the flexible printed circuit board in a height direction is symmetrical with respect to the wiring pattern.

6. A method for manufacturing a wiring board, the method comprising:
preparing a flexible printed circuit board that comprises:
a base having a first opening;
a cover lay having a second opening; and
a wiring pattern sandwiched between the base and the cover lay;
pressing the wiring pattern through the second opening by a bonding tool, and deforming the wiring pattern toward a metal cover; and
bonding together the wiring pattern and the metal cover using the bonding tool.

7. The wiring board according to claim 2, wherein a laminating order of the flexible printed circuit board in a height direction is symmetrical with respect to the wiring pattern.
